(19) United States
(12) Patent Application Publication
(10) Pub. No.: US 2013/0284500 A1
(43) Pub. Date: Oct. 31, 2013

(54) LAMINATE CIRCUIT BOARD STRUCTURE

(71) Applicants: Jun-Chung Hsu, Taoyuan (TW); Chi-Ming Lin, Taipei (TW); Tso-Hung Yeh, New Taipei (TW); Ya-Hsiang Chen, Yunlin (TW)

(72) Inventors: Jun-Chung Hsu, Taoyuan (TW); Chi-Ming Lin, Taipei (TW); Tso-Hung Yeh, New Taipei (TW); Ya-Hsiang Chen, Yunlin (TW)

(21) Appl. No.: 13/455,364

(22) Filed: Apr. 25, 2012

(51) Int. Cl. H05K 1/03; H05K 1/02

(52) U.S. Cl. 174/255; 174/268

(57) ABSTRACT

A laminate circuit board structure from button up including a substrate, a circuit metal layer, a nanometer plating layer and a cover layer is disclosed. The nanometer plating layer is smooth a thickness of 5-40 nm, and can be directly forming on the outer surface of the circuit metal layer or manufactured by firstly forming the nanometer plating layer on a preforming substrate, then pressing the substrate against the nanometer plating layer, and finally removing the preforming substrate. The junction adhesion between the nanometer plating layer and the cover layer or the substrate is improved by chemical bonding. Therefore it does not need to roughen the circuit metal layer or reserve circuit width for compensation such that the density of the circuit increases and much more dense circuit can be implemented in the substrate with the same area.

### BACKGROUND OF THE INVENTION

1. Field of the Invention

The present invention generally relates to a laminate circuit board structure, and more specifically to a structure with improved junction adhesion between the nanometer plating layer and the cover layer or the substrate by chemical bonding without roughening the circuit metal layer.

2. The Prior Arts

Please refer to FIG. 1. The traditional laminate circuit board 1 generally comprises a substrate 10, a circuit metal layer 20 and a cover layer 30, as shown in FIG. 1. The substrate 10 has a rough upper surface, on which the circuit metal layer 20 is formed, and is usually made of at least one of copper, aluminum, silver and gold. The cover layer 30 is made of a binder or a solder resist, used to electrically insulate and protect the circuit metal layer 20. However, the circuit metal layer 20 and the cover layer 30 are made of different materials, so it usually needs to roughen the outer surface 25 of the circuit metal layer 20 through chemical, mechanical or plasma treatment so as to increase the surface friction coefficient and avoid peeling off. The junction property is thus improved by the roughened outer surface 25.

However, one of the shortcomings of the circuit metal layer 20 with the roughened surface in the prior arts is that the design of the circuit on the metal layer is extremely constrained as the circuit becomes much denser because it is necessary to reserve some circuit width to compensate the loss due to the roughening process. Therefore, it needs a laminate circuit board structure without any reserved circuit width to increase the density of the circuit.

### SUMMARY OF THE INVENTION

A primary objective of the present invention is to provide a laminate circuit board structure, which comprises a substrate having a rough upper surface, a circuit metal layer forming on the upper surface of the substrate, a nanometer plating layer formed on the circuit metal layer and having a thickness of 5-40 nm and a rough outer surface with a roughness as Ra <0.35 μm and Rz <3 μm, and a cover layer made of a binder or a solder resist used to cover the circuit metal layer and the nanometer plating layer. The outer surfaces of the circuit metal layer and the nanometer plating layer are smooth and do not have a recognizable roughness by cross-sectional examination through an optical microscope of 1,000 magnifications.

Another objective of the present invention is to provide a laminate circuit board structure, which comprises a substrate having a plurality of mode holes, a nanometer plating layer formed on the mode holes and having a thickness of 5-40 nm and a rough outer surface with a roughness as Ra <0.35 μm and Rz <3 μm, and a circuit metal layer formed on the nanometer plating layer and filling up the mode holes to implement an embedded circuit structure. The outer surface of the nanometer plating layer is smooth and does not have a recognizable roughness by cross-sectional examination through an optical microscope of 1,000 magnifications. Therefore, the circuit metal layer is exposed from the substrate, and the surface of the circuit metal layer is located at the same level with the upper surface of the substrate. The upper surface of the substrate is smooth and has a roughness almost zero, such as Ra <0.35 μm and Rz <3 μm. The above-mentioned laminate circuit board structure is formed by firstly forming the circuit metal layer and the nanometer plating layer on a preforming substrate, then pressing the preforming substrate against the substrate, and finally removing the preforming substrate.

The laminate circuit board structure of the present invention can improve the junction adhesion effect by the chemical bonding formed between the nanometer plating layer and the cover layer or the substrate, and the side effect induced by reserving some circuit width for compensation by roughening the surface of the circuit metal layer is thus overcome because the surface of the laminate circuit board structure is smooth and does not need to reserve any circuit width for compensation. Furthermore, the density of the circuit can increase and much more dense circuit can be implemented in the substrate with the same area.

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic diagram to illustrate the traditional laminate circuit board;

FIG. 2 shows a cross-sectional diagram to illustrate the laminate circuit board structure according to the first embodiment of the present invention; and

FIG. 3 shows a cross-sectional diagram to illustrate the laminate circuit board structure according to the second embodiment of the present invention.

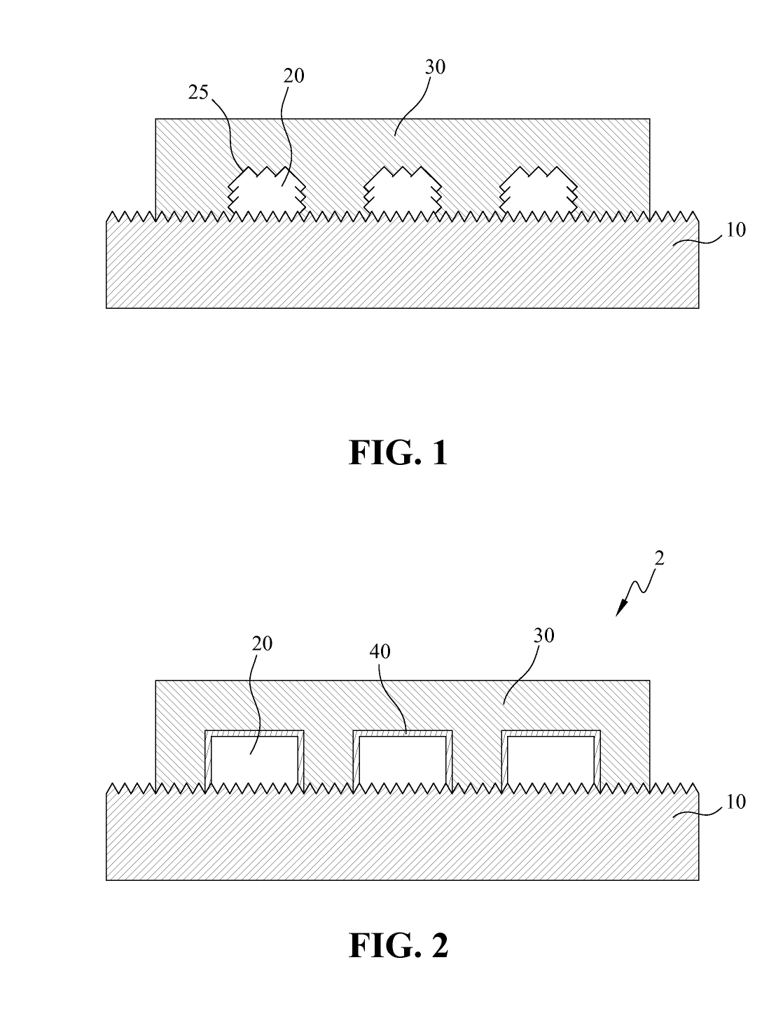

### DETAILED DESCRIPTION OF THE PREFERRED EMBODIMENT

The present invention may be embodied in various forms and the details of the preferred embodiments of the present invention will be described in the subsequent content with reference to the accompanying drawings. The drawings (not to scale) show and depict only the preferred embodiments of the invention and shall not be considered as limitations to the scope of the present invention. Modifications of the shape of the present invention shall too be considered to be within the spirit of the present invention.

Please refer to FIG. 2. The laminate circuit board structure 2 according to the first embodiment of the present invention comprises a substrate 10, a circuit metal layer 20, a cover layer 30 and a nanometer plating layer 40. The substrate 10 is made of FR4 glass fiber or bismaleimide triazime resin (BT resin), and has a rough upper surface. The circuit metal layer 20 is formed on the upper surface of the substrate 10, and made of at least one of copper, aluminum, silver and gold. The cover layer 30 is made of a binder or a solder resist and used to cover the circuit metal layer 20 and the nanometer plating layer 40 which is formed on the outer surface of the circuit metal layer 20. The nanometer plating layer 40 is made of at least two of copper, tin, aluminum, nickel, silver and gold and has a thickness of 5-40 nm and a rough outer surface with a roughness defined by Ra (Arithmetical mean roughness) <0.35 μm and Rz (Ten-point mean roughness) <3 μm. The outer surfaces of the circuit metal layer 20 and the nanometer plating layer 40 are smooth and do not have a recognizable roughness by cross-sectional examination through an optical microscope of 1,000 magnifications.

The circuit metal layer 20 is formed by a traditional image transfer process. The nanometer plating layer 40 is formed on the outer surface of the circuit metal layer 20 by electroless plating (i.e., chemical plating), evaporation, sputtering or atomic layer deposition (ALD) such that the circuit metal layer 20 has three smooth surfaces.

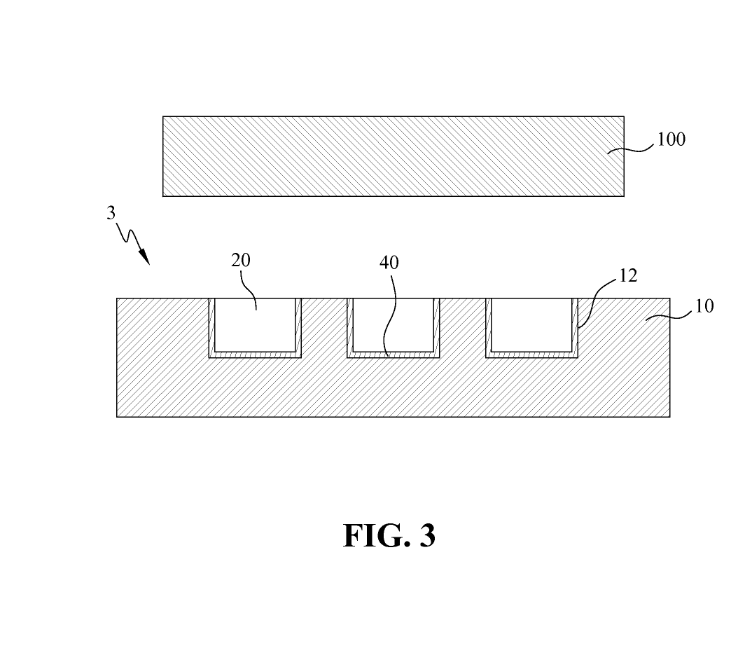

Refer to FIG. 3. The laminate circuit board structure 3 according to the second embodiment of the present invention comprises a substrate 10 having a plurality of mode holes 12, a nanometer plating layer 40 formed on the mode holes 12, and a circuit metal layer 20 formed the nanometer plating layer 40 and fills up the mode holes 12 to implement an embedded circuit structure. The circuit metal layer 20 has a smooth outer surface exposed from the substrate 10 and located at the same level with the upper surface of the substrate 10. The outer surface of the circuit metal layer 20 and the upper surface of the substrate 10 are smooth and each has a roughness defined by Ra <0.35 μm and Rz <3 μm, which can not be recognized by cross-sectional examination through an optical microscope of 1,000 magnifications.

The laminate circuit board structure 3 according to the second embodiment is formed similarly to the above-mentioned process for the laminate circuit board structure 2 according to the first embodiment. Firstly, the nanometer plating layer 40 and the circuit metal layer 20 are formed on a preforming substrate 100. Then, the preforming substrate 100 is pressed against a substrate 10, and finally the preforming substrate 100 is removed to implement the embedded circuit structure. The preforming substrate 100 has a roughness defined by Ra <0.35 μm and Rz <3 μm, which can not be recognized by cross-sectional examination through an optical microscope of 1,000 magnifications. The preforming substrate 100 is a metal plate with a polish surface, such as a copper plate, aluminum plate or steel plate. Or the preforming substrate 100 is an insulation substrate covered with a polish metal film, like the FR4 glass fiber with a polish copper layer or the BT substrate with an aluminum layer. It should be noted that these examples are only illustrative and not intended to limit the present invention. Thus, the circuit metal layer 20 has a structure with four smooth surfaces.

Therefore, the laminate circuit board structure of the present invention can greatly improve the junction adhesion effect between the nanometer plating layer and the cover layer or the substrate by chemical bonding. Additionally, the present invention does not need to roughen the circuit metal layer or reserve circuit width for compensation such that the density of the circuit increases and much more dense circuit can be implemented in the substrate with the same area.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A laminate circuit board structure, comprising:
a substrate, having a rough upper surface;
a circuit metal layer, formed on the upper surface of the substrate;
a nanometer plating layer, formed on the circuit metal layer and having a thickness of 5-40 nm and a rough outer surface with a roughness defined by Ra (Arithmetical mean roughness) <0.35 μm and Rz (Ten-point mean roughness) <3 μm; and
a cover layer, made of a binder or a solder resist, having an outer surface and covering the circuit metal layer and the nanometer plating layer,
wherein the outer surfaces of the circuit metal layer and the nanometer plating layer are smooth and do not have a recognizable roughness by cross-sectional examination through an optical microscope of 1,000 magnifications.

2. The laminate circuit board structure as claimed in claim 1, wherein said substrate is made of FR4 glass fiber or bismaleimide triazime resin, said metal layer is made of at least one of copper, aluminum, silver and gold, and said nanometer plating layer is made of at least two of copper, tin, aluminum, nickel, silver and gold.

3. The laminate circuit board structure as claimed in claim 1, wherein said nanometer plating layer is formed by electroless plating, evaporation, sputtering or atomic layer deposition.

4. A laminate circuit board structure, comprising:
a substrate, having a plurality of mode holes;
a nanometer plating layer, formed on the mode holes and having a thickness of 5-40 nm and a rough outer surface with a roughness defined by Ra <0.35 μm and Rz <3 μm; and
a circuit metal layer, having an outer surface, formed on the nanometer plating layer and filling up the mode holes to implement an embedded circuit structure,
wherein the circuit metal layer is exposed from the substrate, an upper surface of the circuit metal layer is located at the same level with an upper surface of the substrate, the upper surface of the substrate is smooth and has a roughness defined by Ra <0.35 μm and Rz <3 μm, and the upper surface of the substrate, the outer surfaces of the circuit metal layer and the nanometer plating layer are smooth and do not have a recognizable roughness by cross-sectional examination through an optical microscope of 1,000 magnifications.

5. The laminate circuit board structure as claimed in claim 4, wherein said substrate is made of FR4 glass fiber or bismaleimide triazime resin, said metal layer is made of at least one of copper, aluminum, silver and gold, and said nanometer plating layer is made of at least two of copper, tin, aluminum, nickel, silver and gold.

6. The laminate circuit board structure as claimed in claim 4, wherein said circuit metal layer is formed by an image transfer process, said nanometer plating layer is formed by electroless plating, evaporation, sputtering or atomic layer deposition, the preforming substrate is pressed against a substrate, and the preforming substrate is finally removed to implement an embedded circuit structure.

7. The laminate circuit board structure as claimed in claim 5, wherein said preforming substrate has a roughness defined by Ra <0.35 μm and Rz <3 μm which is not cross-sectionally examined by an optical microscope of 1,000 magnifications, and said preforming substrate is a metal plate with a polish surface or an insulation substrate covered with a polish metal film.

8. The laminate circuit board structure as claimed in claim 7, wherein said metal plate is made of a copper plate, aluminum plate or steel plate, said polish metal film is made of a copper layer or an aluminum layer, and said insulation substrate is made of FR4 glass fiber or bismaleimide triazime resin.
